(19) United States
(12) Patent Application Publication
(10) Pub. No.: US 2007/0281434 A1
(43) Pub. Date: Dec. 6, 2007

(54) CAPACITOR OF SEMICONDUCTOR DEVICE APPLYING DAMASCENE PROCESS AND METHOD OF FABRICATING THE SAME

(75) Inventors: Jong-Seon AHN, Gyeonggi-do (KR); Joon KIM, Seoul (KR); Suk-Chul BANG, Gyeonggi-do (KR); Sang-Hoon LEE, Gyeonggi-do (KR); Yung-Jun KIM, Gyeonggi-do (KR); Woo-Soon JANG, Seoul (KR); Eun-Kuk CHUNG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/841,661

(22) Filed: Aug. 20, 2007

Related U.S. Application Data
(62) Division of application No. 10/993,576, filed on Nov. 19, 2004.

(30) Foreign Application Priority Data
Nov. 21, 2003 (KR) 2003-0082972

(51) Int. Cl. H01L 21/20

(52) U.S. Cl. 438/397; 257/E21.09

(57) ABSTRACT

According to embodiments of the invention, a height of a capacitor lower electrode is increased. Portions of the lower electrode and an interlayer insulating layer are etched within the interlayer insulating layer that is formed with the lower electrode thereon, so that a trench having a double damascene structure is formed. A dielectric layer and an upper electrode are formed within the trench. Therefore, shorts between metal interconnects caused by misalignments during formation of the upper electrode are prevented and consistent capacitance values may be secured.

### CROSS REFERENCE TO RELATED APPLICATIONS

This application is a Divisional of U.S. patent application Ser. No. 10/993,576, filed Nov. 19, 2004, now pending, which is claims priority from Korean Patent Application No. 2003-82972, filed on 21 Nov. 2003 in the Korean Intellectual Property Office, the disclosure of which are incorporated by reference in their entirety.

### BACKGROUND OF THE INVENTION

1. Field of the Invention

This disclosure relates to a semiconductor device and a method of fabricating the same, and more particularly to a capacitor of a (SRAM) Static Random Access Memory semiconductor device and a method of fabricating the same.

2. Description of the Related Art

As the trend toward minimizing the dimensions of semiconductor devices continues, the reliability of the semiconductor device becomes more important. However, a semiconductor device, which includes a capacitor therein has a design rule gradually decreased in association with shrinkage of the semiconductor device dimension, thereby resulting in problems such as misalign which degrades reliability of the semiconductor device.

A capacitor for a semiconductor device with a Metal-Insulator-Metal (MIM) structure is generally formed on an interlayer insulating layer that is used for planarization. An example of such a structure is found in U.S. Pat. No. 6,100,155 entitled: Metal-Oxide-Metal Capacitor For Analog Device, issued 8 Aug. 2000.

FIGS. 1 through 8 are sectional views illustrating a method of fabricating a capacitor of a semiconductor device according to a conventional technique.

Referring to FIG. 1, a lower structure 20 that is circuitry of a SRAM semiconductor device including a transistor is formed on a semiconductor substrate 10, using a typical fabricating method. An interlayer insulating layer 30 used for planarization when forming a capacitor is deposited on the lower structure 20. Photolithography and etching are performed, thereby forming contact holes a partially exposing the lower structure. A conductive material, e.g., tungsten (W), is deposited on the semiconductor substrate 10 formed with the contact holes therein, and Chemical Mechanical Polishing (CMP) is carried out. Therefore, the conductive material becomes a metal interconnect 50 that forms a word line inside the interlayer insulating layer 30, lower electrodes 40 of the capacitor, and a metal interconnect 60 for electrical power supply.

Referring to FIGS. 2 and 3, after forming a photoresist pattern 65 on the semiconductor substrate 10 having the capacitor lower electrode 40, an etchant that is highly selective to the tungsten is utilized. Thus, a portion of the interlayer insulating layer 30 between the lower electrodes 40 is etched, thereby forming a trench 70 that exposes a portion of the lower structure 20.

Referring to FIGS. 4, 5 and 6, a dielectric layer 80 is deposited on the semiconductor substrate 10 and within the trench 70. A conductive material 90 that is used for an upper electrode is deposited on the dielectric layer 80, and CMP or etchback is performed to planarize the semiconductor substrate 10. A photoresist pattern 95 is formed on the completely planarized semiconductor substrate 10, and etching is then performed.

Through the etching process, a capacitor that includes the dielectric layer 80A formed between two lower electrodes 40 and upper electrode 90A is formed.

Referring to FIGS. 7 and 8, an interlayer insulating layer 97 is deposited on the semiconductor substrate 10 and then planarized, to form a completely planarized interlayer insulating layer 97A.

However, the conventional method of fabricating the capacitor described above is apt to produce misalign when the second etching that forms the capacitor shown in FIG. 5 is performed, especially when a design rule is small. This is because it is difficult to precisely align an align key during photolithography due to the opacity at the dielectric layer 80 and the conductive material 90.

Once a misalign occurs, the upper electrode 90A of the capacitor may short from a neighboring metal interconnect 50 for word line or a metal interconnect 60 for electrical power supply. Also, a misalign decreases the capacitor area, thereby impeding the goal of consistent capacitance within the semiconductor device.

Moreover, since the upper portion of the interlayer insulating layer 30 is involved in the process of forming the capacitor, the interlayer insulating layer 97 is additionally deposited and is then planarized as shown in FIGS. 7 and 8. Thus, the process becomes complicated.

### SUMMARY OF THE INVENTION

Embodiments of the invention provide a capacitor of a semiconductor device by applying a damascene process, in which the capacitor is formed by a damascene process within an interlayer insulating layer rather than planarizing the interlayer insulating layer, thereby preventing occurrence of misalign and eliminating additional depositing and planarizing the interlayer insulating layer.

Embodiments of the invention also provide a method of fabricating the capacitor of a semiconductor device by applying the damascene process.

According to some embodiments of the invention, a method includes providing a capacitor for a semiconductor device by applying a damascene process on a single-crystal semiconductor substrate. A lower structure that includes circuitry such as a transistor is formed on the semiconductor substrate, and an interlayer insulating layer is formed on the lower structure. Also, a capacitor lower electrode is formed within the interlayer insulating layer by Chemical Mechanical Polishing (CMP), and a trench that forms a double damascene layer is formed by primarily etching the lower electrode within the interlayer insulating layer, and by secondarily etching the interlayer insulating layer between the lower electrodes. A dielectric layer is deposited within the trench as a blanket, and an upper electrode is formed on the dielectric layer that completely fills the trench.

According to some embodiments of the invention, the lower electrode is formed to have a thickness ranging from 3000 to 4000 Å, which is thicker than a thickness of a conventional lower electrode in order to prevent a decrease of the capacitance.

The lower electrode may be formed of tungsten, the dielectric layer may be any one selected from a dielectric material group consisting of TaO, SiN, and HfO, and the upper electrode is formed of TiN.

According to some other embodiments of the invention, a method of fabricating a capacitor of a semiconductor device by applying a damascene process includes forming a lower structure on a semiconductor substrate. Then, an interlayer insulating layer is deposited on the lower structure, and a contact hole that forms a lower electrode for the capacitor is formed. A metal material for the lower electrode is deposited on the interlayer insulating layer to fill the contact hole, and CMP is used on the interlayer insulating layer to form the lower electrode. A photoresist pattern that exposes at least two lower electrodes on the interlayer insulating layer is formed, and a portion of the lower electrodes is primarily etched. The interlayer insulating layer between the lower electrodes is secondarily etched using the primarily etched structure, creating a trench that forms a double damascene. A dielectric layer is deposited on the semiconductor substrate formed with the trench that forms the double damascene as a blanket. Thereafter, a metal material for a capacitor upper electrode is deposited on the semiconductor substrate. Finally, the dielectric layer and the metal material for the upper electrode that remain on the interlayer insulating layer are removed by CMP, using the interlayer insulating layer as a polishing stopper.

According to some embodiment of the invention, it is preferable that the primary etching is performed using an etchant that is highly selective to the interlayer insulating layer. It is preferable that the secondary etching is performed using an etchant that is highly selective to the lower electrode.

According to embodiments of the invention, during formation of a capacitor in a semiconductor device such as a (SRAM) Static Random Access Memory, the capacitor is not formed on the interlayer insulating layer for planarization but is formed within the interlayer insulating layer by the damascene process. Thus, misaligns and shorts between the metal interconnects are prevented while securing a consistent capacitance. Furthermore, because the processes of forming and planarizing an additional interlayer insulating layer after forming the capacitor may be omitted, the fabricating process is simplified.

### BRIEF DESCRIPTION OF THE DRAWINGS

The above and other features and advantages of the invention will become more apparent by describing in detail exemplary embodiments thereof with reference to the attached drawings:

FIGS. 1 through 8 are sectional views illustrating a method of fabricating a semiconductor device according to a conventional technique.

FIGS. 9 through 14 are sectional views illustrating a method of fabricating a capacitor of a semiconductor device applying a damascene process according to some embodiments of the invention.

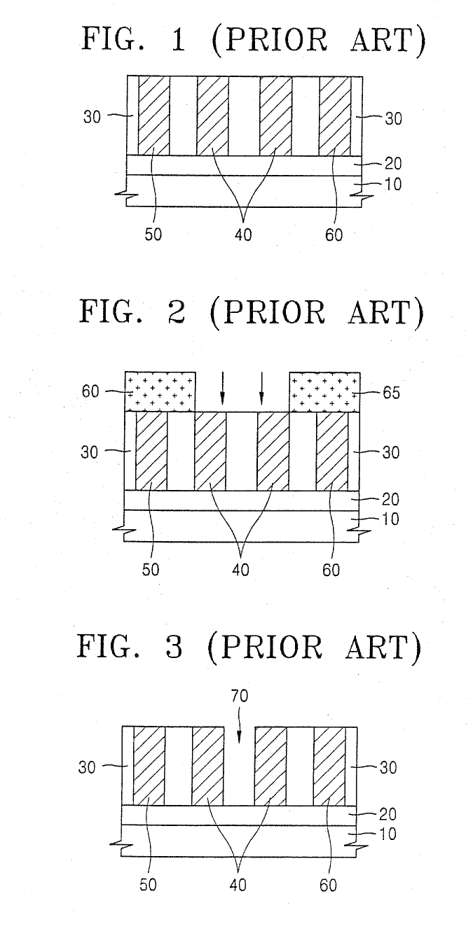

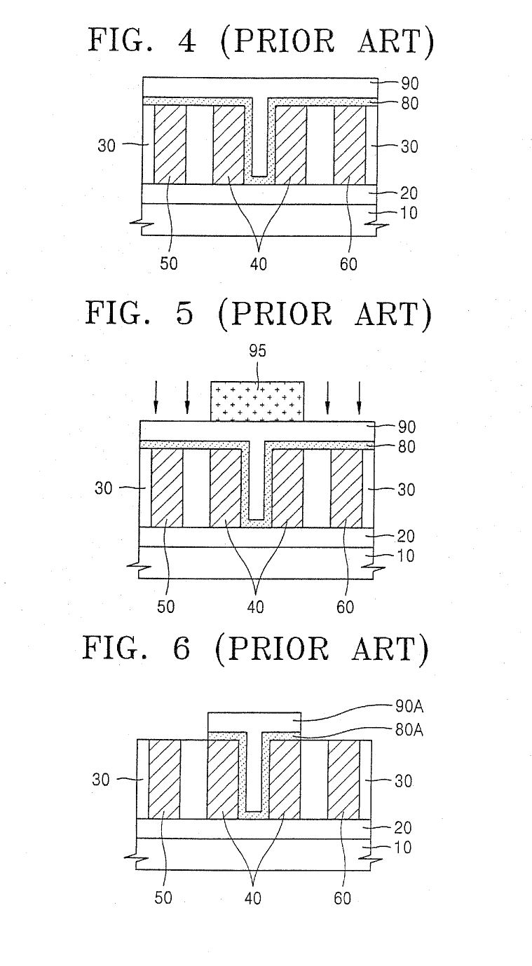

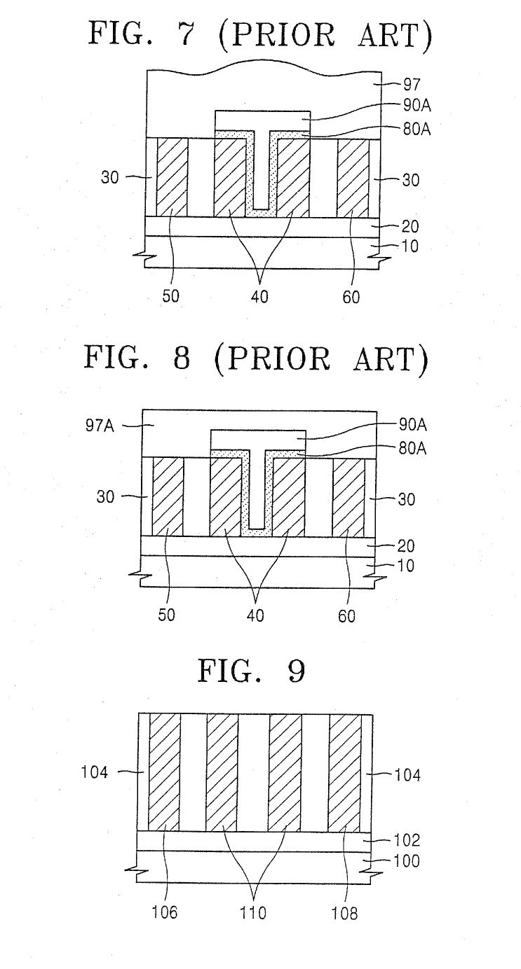

### DETAILED DESCRIPTION OF THE INVENTION

The invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

In the embodiments described below, a capacitor and a method of fabricating the same is described with reference to a SRAM semiconductor device. However, it is apparent that other embodiments may be applied to another semiconductor device such as a DRAM or to integrated type semiconductor device including a SRAM and a DRAM without departing from the teachings of the invention

Now, a capacitor structure of a semiconductor device applying a damascene process according some embodiments of the invention will be described with reference to FIG. 9-14.

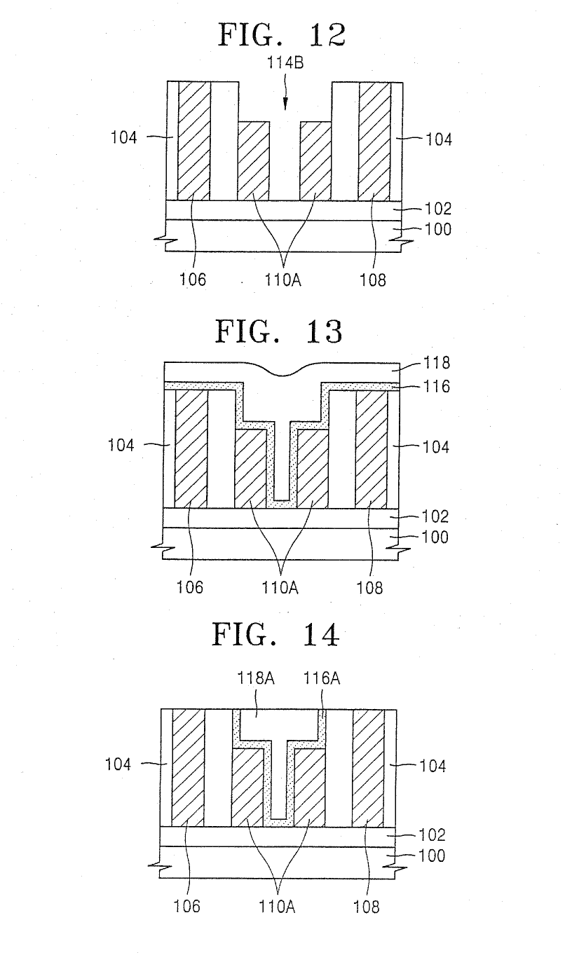

Referring to FIG. 14, the capacitor of the semiconductor device according to some embodiments of the invention includes a single-crystal semiconductor substrate 100, a lower structure 102 that includes circuitry such as a transistor formed on the semiconductor substrate 100, an interlayer insulating layer 104 formed on the lower structure, and a capacitor lower electrode 110A formed on the inside the interlayer insulating layer 104 by CMP. Also, a trench (114B in FIG. 12) forms double damascene by primarily etching the lower electrode 10 within the interlayer insulating layer 104 and by secondarily etching the interlayer insulating layer 104 between the lower electrodes 110. A dielectric layer 116A is deposited along the inside the trench 114B as a blanket, and an upper electrode 118A is formed on the dielectric layer 116A while completely filling the trench 114B.

At this time, the lower structure 102, which includes circuitry such as a transistor, suitably functions as a SRAM. Besides, the interlayer insulating layer 104 may be formed of a material such as an oxide layer or multiple layers including an oxide layer, which is highly selective to the lower electrode 110A during etching. The lower electrode 110A is formed of a conductive material that preferably exerts a good gap fill performance such as tungsten (W).

The lower electrode 110A conventionally has a thickness of about 2100 Å. However, it preferably has a thickness of about 3000˜4000 Å that compensates for a surface area of the lower electrode decreasing due to the damascene process used to form a capacitor.

More preferably, the inside of the interlayer insulating layer 104 is formed with a metal interconnect 106 for word line and a metal interconnect 108 for electrical power supply Vcc, of which shapes equal to those prior to etching the lower electrode 110A. An etched depth of the lower electrode 110A primarily etched in the trench 114B for the purpose of forming the damascene appropriately ranges from 50 to 150 Å. Any high dielectric material such as TaO, SiN, and HfO, may be used as the dielectric layer 80A. Preferably, a TaO layer of 50 to 150 Å allows for relatively simple processing. The upper electrode 90A can be formed of nitride titanium.

FIGS. 9 to 14 are sectional views illustrating a method of fabricating the capacitor of the semiconductor substrate applying the damascene according to some embodiments of the invention.

Referring to FIG. 9, an isolation process is performed with respect to the semiconductor substrate 100 of single-crystal silicon, and the lower structure 102 that is the circuitry of the SRAM including the transistor are formed by the typical method. Then, the interlayer insulating layer 104 is deposited on the lower structure 102 to a thickness of 4000 Å or greater. The thickness of the interlayer insulating layer 104 may be adjusted to make a thickness of the lower electrode (10A in FIG. 14) range from 3000 Å to 4000 Å after forming the capacitor in a subsequent process. At this time, the interlayer insulating layer 102 is preferably formed of an oxide layer or multiple layers that include an oxide layer.

Photolithography and etching are performed on the interlayer insulating layer 104, thereby exposing portions of the lower structure 102. Afterwards, a conductive material is deposited on the semiconductor substrate 100 to fill the contact holes and a surface of the semiconductor substrate 100 is planarized by CMP. Tungsten, which has excellent gap filling performance, may be used as a conductive material. During the CMP planarization, the interlayer insulating layer 104 serves as a polishing stopper.

The metal interconnect 106 for word line, the capacitor lower electrode 110, and the metal interconnect 108 for electric power supply Vcc, which have equal shape, are respectively formed within the interlayer insulating layer 104 by the planarization.

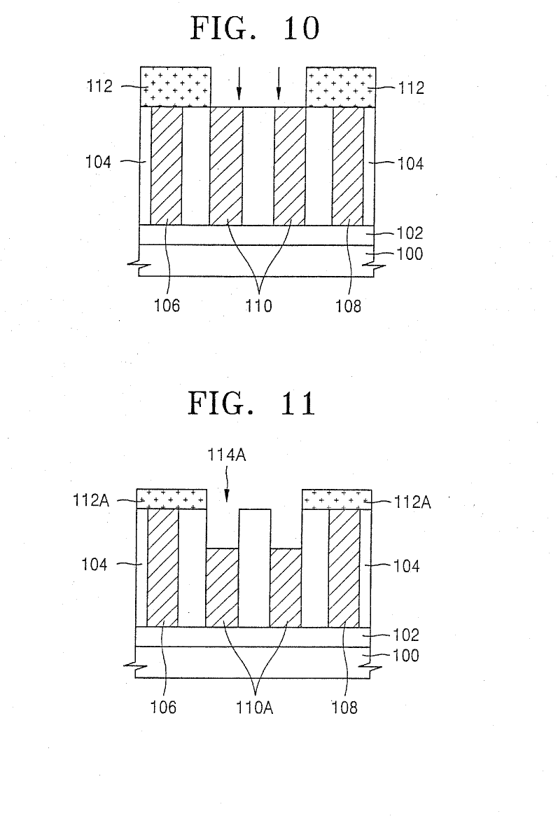

Referring to FIGS. 10, 11, and 12, the photoresist pattern 112 is formed on the semiconductor substrate 100 and the capacitor lower electrodes 10. It is preferable that the photoresist pattern 112 covers an upper surface of the metal interconnect 106 for word lines and the metal interconnect 108 for electric power supply, and exposes an upper portion of the capacitor lower electrode 110. Using the photoresist pattern 112 as an etch mask, the exposed capacitor lower electrode 110 is primarily etched, thereby forming the trench 114A. The etching is preferably dry etching, using an etchant highly selective to the oxide layer that is the interlayer insulating layer 104. At this time, the dry etched depth of the capacitor lower electrode 110A may range from 50 to 150 Å.

Then, a secondary dry etching is performed, by repeatedly using photoresist pattern 112A, thereby removing the interlayer insulating layer 104 that exists between the lower electrodes 110A. Here, an etchant highly selective to tungsten constituting the lower electrode 110A is used, thereby removing the interlayer insulating layer 104, e.g., the oxide layer. The photoresist pattern 112A is removed by ashing, so that the trench 114B that forms the double damascene is formed inside the interlayer insulating layer 104.

Referring to FIGS. 13 and 14, the dielectric layer 116, e.g., a layer of TaO, is deposited to a thickness of 50˜150 Å on the semiconductor substrate 100 formed with the trench 114B that forms the double damascene. The dielectric layer 116 may be formed of any material that can be thinly deposited and has a high dielectric constant, such as SiN, HfO and TaO.

Thereafter, a conductive material, e.g., a nitride titanium layer 118 for an upper electrode, is deposited on the semiconductor substrate 100 and the dielectric layer 116 thereon. A suitable thickness of the upper electrode 118 is of about 1000 Å, which can fill the trench 114B (in FIG. 12). Here, the upper electrode 118 may be formed of another material, which maybe predicted by those of ordinary skill in the art.

Finally, CMP is performed with respect to the semiconductor substrate 100 and the upper electrode 118, thereby removing the upper electrode 118 and the dielectric layer 116, which remain on the semiconductor substrate 100. Therefore, the lower electrode 110A is formed within the interlayer insulating layer 104, and the dielectric layer 116A and the upper electrode 118A are formed within the interlayer insulating layer 104 by the damascene process.

As a result, the upper electrode is formed by etching according to the conventional technique, but is formed by CMP according to embodiments the invention, thereby preventing the occurrence of misaligns. Accordingly, problems such as the short between the metal interconnects conventionally caused by difficult alignment of an align key due to the opaque layers such as the dielectric layer and the upper electrode, and the deviation in capacitance value resulting from the decreased capacitor dimension may be solved. In other words, according to embodiments of the invention, a semiconductor device capacitor having a consistent capacitance value may be formed.

Moreover, since no steps are produced on the semiconductor substrate even after forming the capacitor, an additional interlayer insulating layer is neither deposited nor planarized. Consequently, the deposition and planarization of the interlayer insulating layer are unnecessary, thereby simplifying the process.

Embodiments of the invention may be practiced in many ways. What follows are exemplary, non-limiting descriptions of embodiments of the invention

While the invention has been particularly shown and described with reference to exemplary embodiments thereof, it will be understood by those of ordinary skill in the art that various changes in form and details may be made therein without departing from the spirit and scope of the invention as defined by the following claims.

We claim:

1. A method of fabricating a capacitor comprising:
depositing an interlayer insulating layer on a lower structure that is disposed on a semiconductor substrate; opening at least two contact holes in the interlayer insulating layer;
depositing a first metal material on the interlayer insulating layer to fill the at least two contact holes;
chemically-mechanically polishing the first metal material and the interlayer insulating layer to form at least two lower electrodes exposing the at least two lower electrodes with a photoresist pattern;
etching a portion of the at least two lower electrodes using a first damascene process;
etching the interlayer insulating layer between the at least two lower electrodes using a second damascene process, thereby forming a trench having a double damascene structure;
depositing a dielectric layer on the semiconductor substrate and within the trench;
depositing a second metal material for an upper electrode on the dielectric layer; and
using the interlayer insulating layer as a polishing stopper, chemically-mechanically polishing the dielectric layer and the second metal material to form the upper electrode.

2. The method of claim 1, wherein the lower electrode has a thickness of 3000 to 4000 Å after chemically-mechanically polishing the dielectric layer and the second metal material.

3. The method of claim 1, wherein opening at least two contact holes comprises exposing a portion of the lower structure.

4. The method of claim 1, wherein depositing a first metal material comprises depositing tungsten.

5. The method of claim 1, wherein etching a portion of the at least two lower electrodes using a first damascene process comprises using an etchant highly selective to the interlayer insulating layer.

6. The method of claim 1, wherein etching this interlayer insulating layer between the at least two electrodes using a second damascene process comprises using an etchant highly selective to the lower electrode.

7. The method of in claim 1, wherein etching the interlayer insulating layer between the at least two electrodes using a second damascene process, using the photoresist pattern used during the primary etching.

8. The method of claim 1, wherein the dielectric layer is selected from a high dielectric material group consisting of TaO, SiN, and HfO.

9. The method of claim 1, wherein the second metal material comprises TiN.
